(19) United States
(12) Patent Application Publication
(10) Pub. No.: US 2022/0139703 A1
(43) Pub. Date: May 5, 2022

(54) New precursors for selective atomic layer deposition of metal oxides with small molecule inhibitors

(71) Applicant: The Board of Trustees of the Leland Stanford Junior University, Stanford, CA (US)

(72) Inventors: Josiah Yarbrough, Redwood City, CA (US); Il-Kwon Oh, San Jose, CA (US); Stacey F. Bent, Stanford, CA (US)

(21) Appl. No.: 17/514,788

(22) Filed: Oct. 29, 2021

Related U.S. Application Data
(60) Provisional application No. 63/107,798, filed on Oct. 30, 2020.

(51) Int. Cl. H01L 21/02; C23C 16/455; C23C 16/40

(52) U.S. Cl. CPC H01L 21/02205; H01L 21/02304; H01L 21/0228; C23C 16/407; C23C 16/45553; C23C 16/403; C23C 16/405; H01L 21/02178

(57) ABSTRACT

Improved selective atomic layer deposition of metal oxides is provided that has large-ligand (i.e., molecular weight >20) metal precursors. A small molecule inhibitor on non-growth surfaces is used to distinguish growth surfaces from non-growth surfaces. This approach does not rely on formation of a self-assembled monolayer on the non-growth surfaces.

### CROSS REFERENCE TO RELATED APPLICATIONS

This application claims priority from U.S. Provisional Patent Application 63/107,798 filed Oct. 30, 2020, which is incorporated herein by reference.

### GOVERNMENT SPONSORSHIP

None.

### FIELD OF THE INVENTION

This invention relates to selective atomic layer deposition (ALD) of metal oxides.

### BACKGROUND

Selective atomic layer deposition of Al₂O₃ is an increasingly crucial technology in semiconductor mass production. For example, one important application of selectively deposited Al₂O₃ is in back-end-of-line (BEOL) processing of high-volume manufactured (HVM) semiconductor devices, where the Al₂O₃ is used as a hard mask.

More specifically, with the rapid downsizing and increased complexity of next generation semiconductor devices, fabrication of nanoelectronics requires increasingly sophisticated patterning processes. For example, misalignment errors between layered features have become critically detrimental to device performance and reliability, particularly for increasingly small feature sizes. Specifically, at the BEOL, patterning faces great challenges for the alignment of metal lines and vias as device scaling continues downwards. Typically, an edge placement error at BEOL could lead to shorting or highly resistive vias.

To avoid the limitations from the edge placement errors, a fully self-align via (FSAV) fabrication design has been highlighted. Introducing topography is one strategy to realize the FSAV, which increases the spacing between vias and metal lines. Moreover, the topography allows larger critical via dimension for better metal contact and lower via resistance. For FSAV schemes, metal recess etching and area-selective deposition have been proposed. Although metal recess has been widely adopted in production, it needs multiple steps. Also, metal recess relies on wet-etch chemistry, so it cannot avoid non-uniformity on roughness after etching, leading to the degradation of the electrical properties of vias.

Area-selective deposition is more preferred, with the potential for precise control of thickness together with excellent uniformity, leading to low surface roughness. In order to minimize the effect on the interconnect dielectric capacity, which determines the RC-delay of devices, a material with a high etch contrast with SiOₓ, such as Al₂O₃, is required to create topography at BEOL. Similarly, increasingly thin and conformal high-k dielectric layers are needed for complex 3D architectures present in next generation devices. Conventional methods to facilitate selective ALD with self-assembled monolayers often lack scalability due to liquid-phase processing requirements and reduction in performance with very fine feature sizes.

Selectively deposited Al₂O₃ALD used in conjunction with small molecule inhibitors (SMIs) is an all-vapor phase process that easily integrates into existing deposition schemes to deposit these types of films. Therefore, selective ALD of Al₂O₃ with SMIs is particularly desirable as it allows for deposition with control over material location, thickness, and roughness, thereby facilitating the production of nanoscale feature sizes required for next generation semiconductor devices.

However, the widely used precursor chemical for Al₂O₃ALD both industrially and at research scale is trimethylaluminum (TMA), but this precursor has consistently shown poor selectivity for industrially relevant thicknesses on common substrates. Issues with poor selectivity of Al₂O₃ALD using TMA are likely to be exacerbated as the semiconductor industry moves toward producing devices with sub-5 nm features.

Accordingly, it would be an advance in the art to provide improved selective ALD of Al₂O₃ using small molecule inhibitors.

### SUMMARY

This problem of performing selective Al₂O₃ ALD with SMIs is addressed by selecting a new class of Al precursor. In an example, optimized process parameters (growth temperature, precursor partial pressure, precursor dosing time, purging time, reactant dosing time, and number of cycles) and an ideal SMI, have been used to demonstrate selective ALD of Al₂O₃. We demonstrate that the selective ALD process with unoptimized parameters results in poor selectivity, and that the optimized conditions for selective ALD with the new precursor are very different from those for the normal ALD process. Because of different mechanisms at play between regular ALD and selective ALD, where film growth on the growth surface is based on self-limited surface reactions, different from nucleation inhibition on the non-growth surface, existing technologies of non-selective ALD processes must be modified. Using the developed process with the precursor triethylaluminium (TEA) allows for selective ALD of Al₂O₃ achieving selectivity up to 0.98 with 4 nm thickness on the desired growth surface as a practical example. As a comparative example, selective Al₂O₃ALD using TMA was shown to have relatively poor selectivity.

Significant advantages are provided. We developed a selective ALD process for Al₂O₃, achieving approximately 0.98 selectivity for up to 4 nm of Al₂O₃ grown on Cu and Si—OH, which has not been achievable yet using a widely used Al precursor, TMA. This work provides a practical breakthrough solution using vapor-phase SMIs that selectively adsorb to facilitate the area-selective deposition of Al₂O₃ films.

### BRIEF DESCRIPTION OF THE DRAWINGS

FIG. 1 schematically shows selective atomic layer deposition according to embodiments of the invention.

FIG. 2 is a table showing small molecule inhibitors considered in the experimental work of section B.

FIGS. 3A-B show the dependence of water contact angle on dose time and temperature for one of the SMIs of the experimental work of section B.

FIG. 4 shows the change of water contact angle as ALD growth pulses are performed for a control and two different Al precursors.

FIGS. 5A-B shows molecular spectroscopy results for an SMI coated substrate in the presence of TMA and TEA precursors.

FIGS. 6A-B show selectivity results for TMA and TEA precursors.

FIG. 7A is an image of a bare substrate.

FIG. 7B is an image of the substrate of FIG. 7A after selective ALD of Al₂O₃.

FIG. 7C is an elemental line scan corresponding to the image of FIG. 7B.

### DETAILED DESCRIPTION

Section A is a discussion of general principles relating to embodiments of the invention, and section B is a description of a specific example.

### A) General Principles

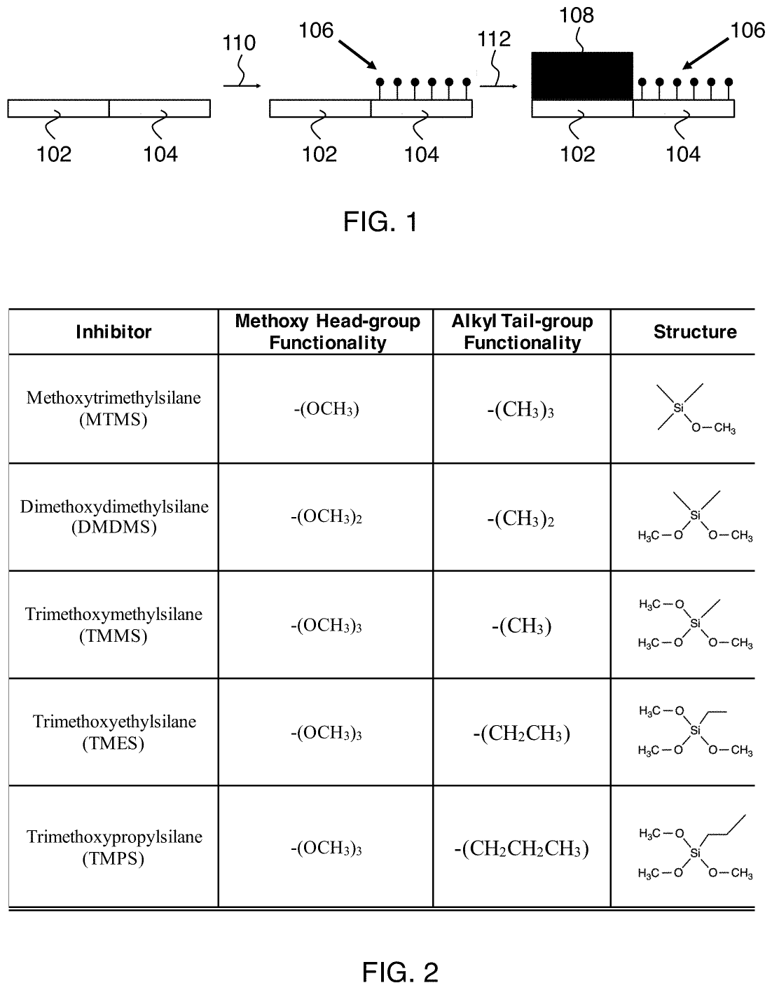

An exemplary embodiment of the invention is shown on FIG. 1. This example is a method of performing selective atomic layer deposition of a metal oxide. A substrate includes one of more first regions 102 and one or more second regions 104. Step 110 is passivating the one or more second regions 104 with a small molecule inhibitor (SMI) to provide a passivation-patterned surface 106. Step 112 is performing atomic layer deposition of the metal oxide 108 on the passivation-patterned surface 106 such that the metal oxide 108 is deposited on the one or more first regions 102 but not deposited on the one or more second regions 104.

The precursor for the atomic layer deposition of the metal oxide has a molecular structure having a metal species bound to organic ligands, where the metal species corresponds to the metal oxide, and wherein the organic ligands all have a molecular weight greater than 20. For example, the organic ligands can be linear chain alkyl groups having a formula given by —CₙH₂ₙ₊₁ for n≥2. The case n=2 for aluminum is considered below in section B, where the precursor is Al(C₂H₅)₃. Other representative precursors include: tetrakis(diethylamido)hafnium Hf(N(C₂H₅)₂)₄ and aluminum-tri-sec-butoxide-Al(OCH(CH₃)C₂H₅)₃.

Without being bound by theory, it is believed that the relatively large-ligand precursors defined above are less able to penetrate an adsorbed layer of SMI on a substrate than small-ligand precursors, thereby improving ALD selectivity. Section B below shows a specific example consistent with this hypothesis, where an Al(C₂H₅)₃ precursor (large ligand) provides selective ALD with an SMI inhibitor, but an Al(CH₃)₃ precursor (small ligand) does not provide selective ALD with an SMI inhibitor.

Therefore, it is expected that the present approach will be applicable to growth of a wide variety of metal oxides, since the apparent advantage of large-ligand precursors should be independent of the metal in the precursor. In the example described below, Al is the metal species. However, as indicated here, it is expected that the present approach is also applicable to selective ALD of other metal oxides. Accordingly, suitable metal species include, but are not limited to: Al, Zn, Ga, In, Zr, Ti and Hf.

The SMI has a maximum molecular dimension of 1 nanometer, and has a vapor pressure of at least 5 Torr at 20 degrees Celsius. The SMI also includes a functional group that reacts with the substrate to form a surface adsorbed species and a hydrocarbon group. Hydrocarbon groups in the surface adsorbed species are independent of each other. Here this independence is understood to refer to the hydrocarbon groups on one SMI molecule being independent of the hydrocarbon groups on any other SMI molecule in the surface adsorbed species. The net result of this independence is that a self-assembled monolayer is not formed in the SMI surface adsorbed species. In other words, these hydrocarbon groups do not contribute to self-assembly by stabilizing surface adsorption of the SMI through interactions with hydrocarbon groups on neighboring surface-adsorbed SMI molecules.

The SMI can be an organosilicon compound, where an organosilicon compound is an organic compound with one or more silicon-carbon bonds.

Preferably, the first and second regions have dissimilar compositions. In such cases, it is preferred for these compositions and the SMI to be chosen such that exposure of the entire substrate to the SMI leads to selective adsorption of the SMI only on the second regions. In this way, no masking step is needed to define the pattern for the selective ALD growth.

Practice of the invention does not depend critically on the compositions of the first and second regions.

Exemplary materials for the second regions (non-growth surfaces) include SiO₂; metal oxides such as HfO₂, ZrO₂, Al₂O₃, Cr₂O₃, MnO₂, CuO, SnO₂, and TiO₂; and nitrides such as SiN, TiN, and TaN. Materials chemically similar to silicon oxide can be used as the materials where deposition of the metal oxide is blocked by the SMIs. Here the most relevant parameter for chemical similarity appears to be surface —OH density. Surface acidity (SA) is also relevant, more for deposition time than for deposition selectivity.

Exemplary materials for the first regions (growth surfaces) include Cu, Pt, Au, Ag, Co, and Ru. Materials chemically similar to copper can be used as the material on which the metal oxide is deposited. Here also the most relevant parameter for chemical similarity appears to be surface —OH density. Surface acidity is also relevant, more for deposition time than for deposition selectivity.

### B) Example

FIG. 1 is a schematic for the selective growth studied in this work. Organosilicon small molecule inhibitors (SMIs) were used as inhibitors for metal-dielectric patterned substrates. These substrates were first exposed to the SMI before subsequent exposure to a standard ALD (atomic layer deposition) process, without breaking vacuum. ALD processes using trimethylaluminum (TMA) and triethylaluminum (TEA) as the aluminum precursors and water as a co-reactant were done to prepare Al₂O₃ thin films under N₂ purge gas.

FIG. 2 is a table listing the SMIs that were used in this work. Exposures for each inhibitor were standardized to 45 Torr-min for each experiment, with bubbler temperatures between 20-50° C. required for sufficient vaporization of each SMI. These SMIs are methoxytrimethylsilane (MTMS), dimethoxydimethylsilane (DMDMS), trimethoxymethylsilane (TMMS), trimethoxyethylsilane (TMES), and trimethoxypropylsilane (IMPS).

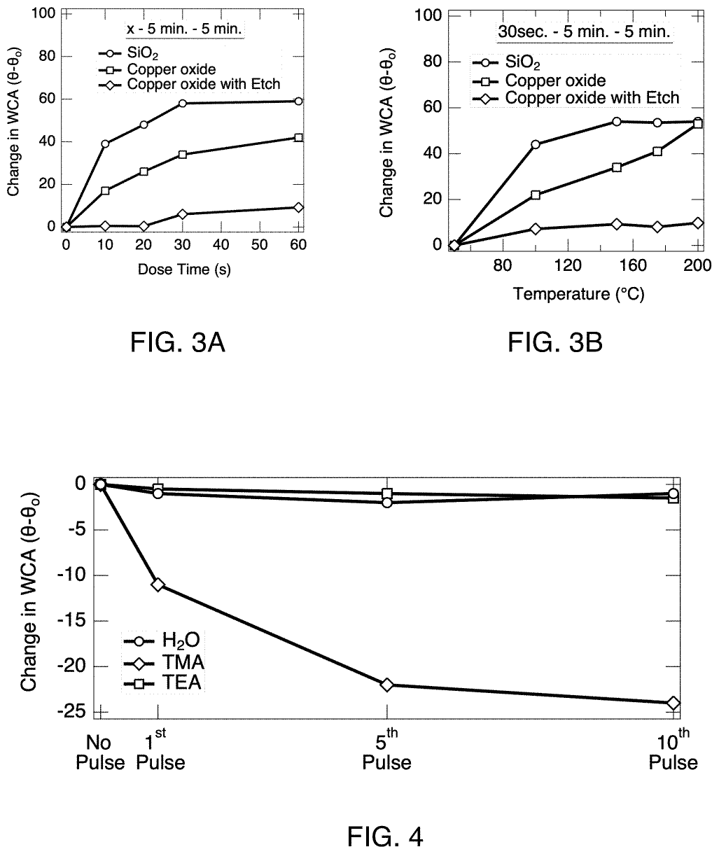

FIGS. 3A-B show changes in water contact angle (WCA) for DMDMS on SiO₂, copper oxide, and copper (oxide etched away) with variations in (FIG. 3A) dose time and (FIG. 3B) substrate temperature. Process conditions are displayed as dose time-soak time-purge time.

FIGS. 3A-B show the results of adsorption of one of the SMIs, DMDMS, on three substrates: SiO₂, copper oxide, and copper (with the oxide etched away by an acetic acid bath). Total uptake of the SMI on the substrate is reflected in the difference between the original WCA and the new WCA upon adsorption, thus the figures plot changes in WCA as a function of either dose time or adsorption temperature. As shown in FIGS. 3A-B, the WCA depends strongly on the substrate, dose time, and reaction temperature. For the copper oxide and SiO₂ surfaces, the WCA generally increases with DMDMS dose as well as with substrate temperature, indicating increasing adsorption of the DMDMS molecule at the surface since the methyl-terminated surface is more hydrophobic (higher WCA) than the hydroxyl-terminated surface. Based on the WCA curves, surface reaction rates between DMDMS and the native oxides of copper and silicon appear similar, with both surfaces showing quick uptake of the SMI with 10 s of dosing (FIG. 3A). However, the two oxidic surfaces differ in the saturation times, with DMDMS saturating the SiO₂ substrate after 30 s of DMDMS dosing, while more than 60 s is required for saturation on the copper oxide. On the other hand, the bare (etched) copper surface reveals a different saturation profile: across all dose times studied, the WCA and hence DMDMS surface coverage remains low. Moreover, the WCA remains low on etched copper even at higher substrate temperatures up to 200° C., suggesting that there is no facile reaction pathway for DMDMS to adsorb on bare copper (FIG. 3B).

In FIG. 4, the change in WCA relative to that of TMPS-passivated SiO₂ is plotted following increased exposure to H₂O, TMA, or TEA. Water did not induce significant changes in the surface energy at the optimized temperature of 150° C., suggesting that the passivated surface is reasonably inert to this precursor. The aluminum precursors show a more divergent effect at the surface. After just one pulse, TMA quickly induces the development of a more hydrophilic interface and continues to degrade the hydrophobic surface with subsequent pulses. On the other hand, TEA does not significantly impact the WCA of the TMPS passivation layer across 10 pulses of this precursor, similar to the water.

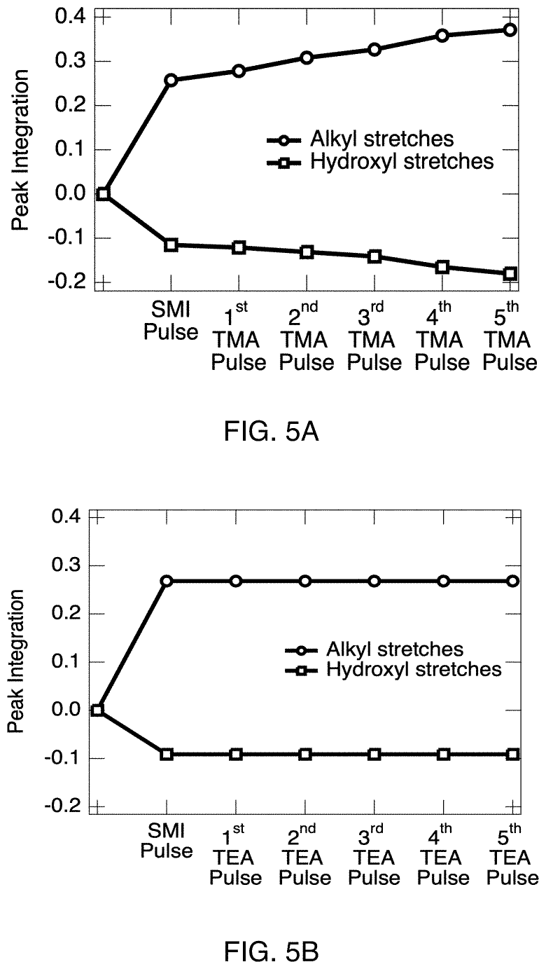

FIGS. 5A-B show integrated peak areas for alkyl and hydroxyl stretching modes taken from in-situ FTIR (Fourier Transform Infrared) spectra comparing the effects of (FIG. 5A) TMA and (FIG. 5B) TEA pulses on TMPS-passivated SiO₂ gel. The relative inertness of TMPS-passivated SiO₂ to TEA compared to TMA was probed further with in situ FTIR spectroscopy. Spectra were collected for as prepared TMPS-exposed SiO₂ as well as after successive pulses of either TMA or TEA. Chemisorption of both the SMI and Al precursor can be followed by the appearance of C—H symmetric and antisymmetric vibrational stretching modes (2900-3000 cm⁻¹), and by the relative disappearance of similar excitations from surface-bound hydroxyl groups (3650-3750 cm⁻¹) present on the SiO₂ substrate. The integrated C—H stretching modes and OH stretches are plotted in FIGS. 5A-B as a function of SMI and TMA or TEA exposure. In both experiments, pulses of the SMI resulted in an initial increase of the C—H vibrational modes and reduction of the O—H excitation modes, as expected upon adsorption of TMPS due to the presence of the terminating methyl group on TMPS, as well as the ligand exchange reaction between surface hydroxyls and TMPS that reduces the density of O—H reactive sites. Subsequent Al precursor pulses led to different spectral behavior depending on whether TEA or TMA was used. The integrated intensity of both the alkyl and hydroxyl stretches remains unchanged with consecutive TEA pulses, consistent with the lack of reaction between this precursor and the TMPS-passivated SiO₂ gel (FIG. 5B). Conversely, successive TMA pulses increase the integrated intensity of the C—H modes and decrease that of the O—H modes (FIG. 5A), suggesting chemisorption of the TMA precursors and removal of some hydroxyl groups. The result indicates that even in the presence of the inhibitive TMPS-passivation layer, TMA can react at the surface.

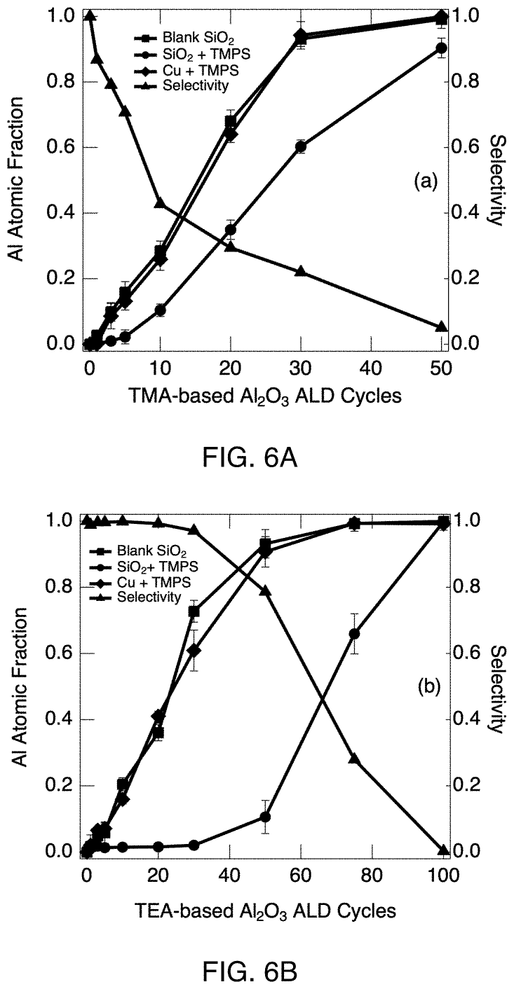

FIGS. 6A-B show the atomic fraction of aluminum on various TMPS-treated and untreated substrates as a function of ALD cycles for a TMA-based Al₂O₃ALD process (FIG. 6A) as well as TEA-based Al₂O₃ALD process (FIG. 6B). Growth on reference unpassivated SiO₂ substrates is also shown. Plotted in each figure is Al atomic fraction determined by XPS as a function of ALD cycle number as well as selectivity on TMPS-exposed copper over TMPS-exposed SiO₂, defined in Eq. 1 below.

For both precursors, with increasing number of Al₂O₃ALD cycles, the Al atomic fraction on copper substrates exposed to TMPS is nearly indistinguishable from that on blanket SiO₂ substrates, further supporting our earlier observation with WCA goniometry that TMPS has limited adsorption on etched copper substrates. For TMA-based Al₂O₃ALD, the nucleation delay caused by TMPS passivation on SiO₂ was slight yet distinct compared to blanket SiO₂, with nucleation beyond 5 cycles of ALD leading to reliable growth. On the other hand, TEA-based Al₂O₃ALD on TMPS-passivated SiO₂ had a nucleation delay that extended beyond 30 cycles of Al₂O₃ALD, compared to Al₂O₃ growth on blanket SiO₂ substrates like that of TMA-supported Al₂O₃ALD.

To quantify the selectivity, we compared relative amounts of Al₂O₃ deposition on nongrowth (NGS) and growth (GS) surfaces, as shown in the following equation.

$${S}_{x} = \frac{{R}_{GS} - {R}_{NGS}}{{R}_{GS} + {R}_{NGS}} \qquad ( 1 )$$

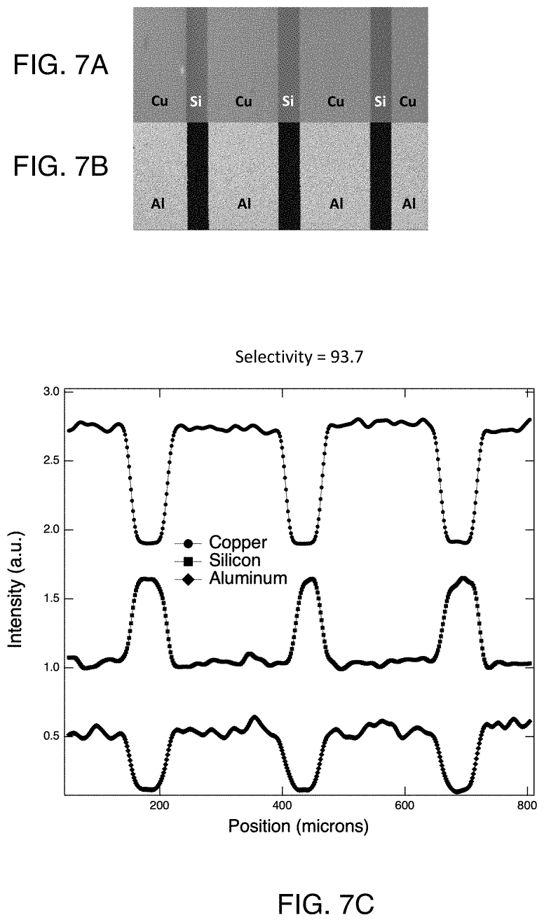

An SEM image was produced to show the structure of the patterned substrate before Al₂O₃ deposition, where 50 μm-wide SiO₂ features were produced between 200 μm-wide Cu lines (FIG. 7A). This patterned substrate was then subjected to the same TEA process as performed on the blanket Cu and SiO₂ substrates, where TMPS was first pulsed, followed by 30 cycles of Al₂O₃ALD with TEA and water. As shown from the elemental mapping produced from AES (FIG. 7B), Al₂O₃ growth is abundant in the copper region, while remaining well-inhibited in the silicon region, clearly demonstrating the facility of this process to produce selective growth. An elemental line scan performed with AES further verified this selective growth (FIG. 7C), where selective growth of Al₂O₃ on copper is inferred from the aluminum signal only increasing in tandem with the copper signal. Aluminum intensities from this line scan in the GS (copper) and NGS (SiO₂) regions can be compiled and ratioed against their respective substrate intensities to produce a cumulative value for selectivity using the method described above (Eq. 1). The selectivity of the process in FIGS. 7A-C, 93.7%, describes highly selective growth, with Al₂O₃ limited to growing in preferred copper regions.

1. A method of performing selective atomic layer deposition (ALD) of a metal oxide, the method comprising:
preparing a substrate having one or more first regions and one or more second regions;
passivating the one or more second regions with a small molecule inhibitor (SMI) to provide a passivation-patterned surface, wherein the SMI has a maximum molecular dimension of 1 nanometer, wherein the SMI has a vapor pressure of at least 5 Torr at 20 degrees Celsius, wherein the SMI includes a functional group that reacts with the substrate to form a surface adsorbed species and a hydrocarbon group, and wherein hydrocarbon groups in the surface adsorbed species are independent of each other;
performing atomic layer deposition of the metal oxide on the passivation-patterned surface such that the metal oxide is deposited on the one or more first regions but not deposited on the one or more second regions;
wherein a precursor for the atomic layer deposition of the metal oxide has a molecular structure having a metal species bound to organic ligands, wherein the metal species corresponds to the metal oxide, and wherein the organic ligands all have a molecular weight greater than 20.

2. The method of claim 1, wherein the metal species is selected from the group consisting of: Al, Zn, Ga, In, Zr, Ti and Hf.

3. The method of claim 1, wherein the SMI is an organosilicon compound.

4. The method of claim 1, wherein the first and second regions have dissimilar compositions.

5. The method of claim 4, wherein exposure of the entire substrate to the SMI leads to selective adsorption of the SMI on the second regions.

6. The method of claim 1, wherein the organic ligands are linear chain alkyl groups having a formula given by —CₙH₂ₙ₊₁ for n≥2.
